(19) United States
(12) Patent Application Publication
(10) Pub. No.: US 2011/0024162 A1
(43) Pub. Date: Feb. 3, 2011

(54) FLEXIBLE WIRING UNIT AND ELECTRONIC APPARATUS

(75) Inventor: Akira Oikawa, Tokyo (JP)

Correspondence Address: Ditthavong Mori & Steiner, P.C., 918 Prince Street, Alexandria, VA, 22314, US

(73) Assignee: SUMITOMO BAKELITE CO., LTD., Tokyo (JP)

(21) Appl. No.: 12/935,584

(22) PCT Filed: Apr. 8, 2009
(86) PCT No.: PCT/JP2009/001624

§ 371 Date: Sep. 30, 2010

(30) Foreign Application Priority Data
Apr. 21, 2008 (JP) 2008-110767
Apr. 21, 2008 (JP) 2008-110768

(51) Int. Cl. H05K 1/02

(52) U.S. Cl. 174/254

(57) ABSTRACT

A flexible wiring unit (100) includes a flexible substrate (50) having flexibility in a longitudinal direction, including a signal line (30) for transmitting and receiving signals to and from an external circuit, a front insulating layer (20) and a back insulating layer (40) holding the signal line therebetween, and a shield layer (10) provided on an upper face of the front insulating layer (20); a non-conductive substrate spacer (62) provided so as to oppose a lower face of the back insulating layer (40); and a support member (61) that sustains a longitudinal end portion of the flexible substrate (50); and the other longitudinal end portion is movable. A distance (Y) between a back face of the substrate spacer (62) and the signal line (30) in a state where the flexible substrate (50) is in contact with a surface of the substrate spacer (62) is longer than a distance (X) between a lower face of the shield layer (10) and the signal line (30).

### TECHNICAL FIELD

The present invention relates to a flexible wiring unit that includes a flexible substrate having flexibility in a longitudinal direction, and to an electronic apparatus that utilizes the flexible wiring unit.

### BACKGROUND ART

Such type of flexible substrate is widely employed for the wiring of the electronic apparatus that includes a movable portion. The flexible substrate is widely applicable to, for example, an optical head of a disk drive unit, a flip down type monitor unit, a printer head, a clam-shell type mobile phone and laptop computer, and so forth.

FIG. 7 schematically depicts a disk drive unit 1200, and FIG. 8 a flip down monitor unit 1300, as examples of the conventional electronic apparatus.

The conventional disk drive unit can be found, for example, in the patent document 1. An example of the conventional flip down monitor unit can be found in the patent document 2.

The disk drive unit 1200 shown in FIG. 7(a) essentially includes a flexible wiring unit 1100 and a disk drive mechanism 1220, both installed on a metal base 1210 having a flat upper face.

The flexible wiring unit 1100 includes a head unit 1120, a connector 1110, a flexible substrate 1050, and a support member 1061. The head unit 1120 writes and reads data in and from a donut-shaped disk 1223 driven to rotate by a disk drive mechanism 1220. The connector 1110 electrically connects the flexible wiring unit 1100 and an external apparatus (not shown). The flexible substrate 1050 connects the head unit 1120 and the connector 1110. The support member 1061 serves to fix a base portion of the flexible substrate 1050 and the connector 1110 to the metal base 1210.

Generally, the flexible substrate 1050 and the support member 1061 are bonded by means of an adhesive layer 1130. The support member 1061 is made of a non-conductive material such as Polyethylene Terephthalate (PET), polyimide, or glass epoxy, and formed in a predetermined plate thickness.

The disk drive mechanism 1220 includes a disk retainer 1222 that sustains the disk 1223, and a driving motor 1221 that drives the disk retainer 1222 so as to axially rotate.

In the conventional example shown in FIGS. 7(a) and 7(b), the support member 1061 is located close to the driving motor 1221, and the connector 1110 is fixed to the support member 1061 on the side of the driving motor 1221. The head unit 1120 is located at a distal end portion of the flexible substrate 1050, and guided to a predetermined position with respect to the track, by a head moving mechanism (not shown). As shown in FIG. 7(a), in the case where the head unit 1120 is to make access to a track in an inner region of the disk 1223, the head unit 1120 is driven by the head moving mechanism to a backward position of the flexible wiring unit 1100 (to the right in FIGS. 7(a) and 7(b)). When the head moving mechanism guides the head unit 1120 to a position above the connector 1110, the head unit 1120 can make access to the desired track. At this moment, the flexible substrate 1050 is bent in a horizontal U-shape.

The flexible substrate 1050 includes, as shown in FIG. 7(b), a front and a back insulating layer 1020, 1040 opposing each other and a signal line 1030 interleaved therebetween, with optionally provided additional layers such as a shield layer 1010, formed on an upper face of those layers.

Normally, the front and the back insulating layer 1020, 1040 are formed in the same thickness.

The flexible substrate 1050 bears predetermined flexibility and rigidity in a certain balance.

Accordingly, in the case where the head unit 1120 is located above the support member 1061, or particularly above the connector 1110 as shown in FIG. 7(a), the flexible substrate 1050 deformed in the horizontal U-shape floats above the metal base 1210 without making contact therewith. In this state, it is only a small portion of the front-to-back length of the flexible substrate 1050 that is opposing the metal base 1210.

In contrast, in the case where the head unit 1120 is to make access to a track in an outer region of the disk 1223 as shown in FIG. 7(b), the head unit 1120 driven forward by the head moving mechanism (not shown), i.e. to the left in FIGS. 7(a) and 7(b), away from the position above the connector 1110. The flexible substrate 1050, the distal end portion of which is fixed to the head unit 1120, follows the head unit 1120 thus to be deformed. FIG. 7(b) depicts the state where the flexible substrate 1050 has been deformed from the U-shape to a J-shape. In the flexible substrate 1050 deformed in to the J-shape as shown in FIG. 7(b), a longer portion of the front-to-back length opposes the metal base 1210, compared with the U-shape shown in FIG. 7(a). Also, when the head unit 1120 moves to an outer periphery of the disk 1223, the flexible substrate 1050 is pressed so as to be more distant from the head unit 1120, i.e. downward in FIGS. 7(a) and 7(b), and resultantly an intermediate portion in the longitudinal direction is pressed against the metal base 1210.

Meanwhile, the flip down monitor unit 1300 shown in FIGS. 8(a) and 8(b) is widely employed in a displayer for rear seats of a vehicle.

FIG. 8(a) depicts the state where a monitor 1330 of the flip down monitor unit 1300 is stored inside a recessed metal base 1310, constituting a part of the ceiling of the vehicle.

FIG. 8(b) depicts the flip down monitor unit 1300 in use, where the monitor 1330 has been rotated about a hinge 1333 clockwise in FIGS. 8(a) and 8(b), so that the display screen 1332 is opened and exposed.

Generally the monitor 1330 includes the display screen 1332 and a driver circuit 1331 that drives the display screen 1332 with respect to each pixel, installed in a metal housing 1335.

Signal transmission and reception between the driver circuit 1331 and the external apparatus (not shown) is executed through the flexible wiring unit 1100. The metal housing 1335 includes a wiring slot 1334, through which the driver circuit 1331 located inside the metal housing 1335 and the external apparatus are connected by means of the flexible substrate 1050.

The flexible wiring unit 1100 includes the flexible substrate 1050, and a support member 1061 that fixes a base portion of the flexible substrate 1050 to the metal base 1310.

The flexible substrate 1050 transmits an output signal received from the external apparatus located on a back of the ceiling of the vehicle (upper face side of the metal base 1310), to the driver circuit 1331.

In the conventional example shown in FIGS. 8(a) and 8(b), when the monitor 1330 rotates from the closed state (FIG. 8(a)) to the open state (FIG. 8(b)), the driver circuit 1331, to which the distal end portion of the flexible substrate 1050 is fixed, is displaced, thereby reducing the path length to the support member 1061.

The flexible substrate 1050 is deformed upon following the opening and closing action of the monitor 1330. Because of the decrease in path length, an intermediate portion of the flexible substrate 1050 swells, so that a portion thereof is pressed against the metal base 1310 as shown in FIG. 8(b).

Patent document 1: JP-A No. 2000-173200

Patent document 2: JP-A No. 2007-153303

### DISCLOSURE OF THE INVENTION

The conventional disk drive unit 1200 and the flip down monitor unit 1300 bear a drawback that the change in positional relationship between the flexible substrate 1050 and the metal base 1210, 1310 causes fluctuation in characteristic impedance of the flexible substrate 1050.

In the case of the disk drive unit 1200 shown in FIGS. 7(a) and 7(b), for example, when the head unit 1120 moves forward from the backward position, the front-to-back length of the flexible substrate 1050 opposing the metal base 1210 is changed. At this moment, also, the flexible substrate 1050 is pressed against the metal base 1210. In the case where the front and the back insulating layer 1020, 1040, holding the signal line 1030 therebetween, have the same thickness, the distance between the surface of the metal base 1210 and the signal line 1030 is the same as the distance between the lower face of the shield layer 1010 and the signal line 1030. In other words, when the head unit 1120 moves forward from the backward position, the signal line 1030 comes very close to the metal base 1210.

This leads to an increase in static capacitance between the conductive signal line provided in the flexible substrate 1050 and the metal base 1210, which generally lowers a characteristic impedance Z₀ of the flexible substrate 1050.

This is also the case with the flip down monitor unit 1300 shown in FIGS. 8(a) and 8(b). The decrease in distance between the signal line 1030 and the metal base 1310, caused by the opening action of the monitor 1330 which presses the flexible substrate 1050 against the metal base 1310, results in an increase in static capacitance therebetween, which generally lowers a characteristic impedance Z₀ of the flexible substrate 1050.

Here, the flexible substrate is required to match the characteristic impedance with another transmission line, device, or electronic apparatus to which the flexible substrate is connected. This is because unmatched impedance with the connected electronic apparatus provokes reflection of the signal being transmitted at a connection point, thereby creating a turbulent waveform thus resulting in degraded S/N ratio. Accordingly, the flexible substrate bears the characteristic impedance designed in advance, and therefore the fluctuation in characteristic impedance arising from the change in positional relationship with the metal base should be prevented by all means.

The present invention has been accomplished in view of the foregoing problem, with an object to provide a flexible wiring unit that can suppress fluctuation in characteristic impedance arising from movement of a distal end portion of the flexible substrate, and an electronic apparatus that utilizes such flexible wiring unit.

According to the present invention, there is provided a flexible wiring unit comprising: a flexible substrate having flexibility in a longitudinal direction, including a signal line used for transmitting and receiving a signal to and from an external circuit, a front insulating layer and a back insulating layer with the signal line interleaved therebetween, and a conductive shield layer provided on an upper face of the front insulating layer so as to cover at least a part of the signal line;

a non-conductive substrate spacer provided so as to oppose a lower face of the back insulating layer;

a support member that sustains a longitudinal end portion of the flexible substrate;

the other longitudinal end portion of the flexible substrate being movably disposed;

wherein a distance Y between a back face of the substrate spacer and the signal line in a state where the flexible substrate is in contact with a surface of the substrate spacer is longer than a distance X between a lower face of the shield layer and the signal line.

In the present invention, the expression that the flexible substrate is in contact with the surface of the substrate spacer includes the state where these are in indirect contact via another intermediate layer, in addition to the state where these are in direct contact.

In the present invention, the front/back insulating layers and the shield layer may be stacked in a plurality of layers. In the case where a plurality of conductive layers is provided on the upper face of the front insulating layer, the layer closest to the signal line will be called the shield layer, and a distance between the lower face of such shield layer and the signal line will be taken as the distance X.

In a more specific embodiment, in the flexible wiring unit according to the present invention the support member may be non-conductive,

and a distance Z between a back face of the support member and the signal line may be three times or more as long as the distance X between the lower face of the shield layer and the signal line the shield layer.

According to the present invention, there is also provided an electronic apparatus, comprising:

a metal base;

a flexible substrate having flexibility in a longitudinal direction, including a signal line used for transmitting and receiving a signal to and from an external circuit, a front insulating layer and a back insulating layer with the signal line interleaved therebetween, and a conductive shield layer provided on an upper face of the front insulating layer so as to cover at least a part of the signal line;

a non-conductive substrate spacer provided so as to oppose a lower face of the back insulating layer, and a support member that sustains a longitudinal end portion of the flexible substrate, both located on the metal base;

wherein the other longitudinal end portion of the flexible substrate is movably disposed; and

a distance between the metal base and the signal line in a state where the flexible substrate is in contact with a surface of the substrate spacer is longer than a distance between a lower face of the shield layer and the signal line.

It is to be noted that the constituents of the present invention do not necessarily have to be individually independent, but a plurality of constituents may form a piece of component; a constituent may be composed of a plurality of components; a constituent may be a part of another constituent; and a part of a constituent may also serve as a part of another constituent.

Although the present invention specifies the back and forth, up and downward, and left and right direction, those are merely for convenience sake for simplifying the explanation of positional relations between the constituents of the present invention, and in no way intended to limit the direction in the manufacturing process or in the use of the product, in the execution of the present invention.

The flexible wiring unit according to the present invention and the electronic apparatus including the flexible wiring unit can suppress the fluctuation in characteristic impedance arising from the movement of the distal end portion of the flexible substrate, thereby assuring high-quality transmission and reception of signals through the signal line.

### BRIEF DESCRIPTION OF THE DRAWINGS

The above and other objects, features and advantages will become more apparent through a preferred embodiment described hereunder and the following accompanying drawings.

FIGS. 1(a) and 1(b) are schematic side views showing a flexible wiring unit according to a first embodiment;

FIG. 2 is an enlarged cross-sectional view of a region C shown in FIG. 1;

FIG. 3 is an enlarged cross-sectional view of a region D shown in FIG. 1;

FIGS. 4(a) and 4(b) are schematic side views showing a disk drive unit as an example of an electronic apparatus;

FIGS. 5(a) to 5(c) are schematic side views showing a flexible wiring unit according to a second embodiment, and a flip down monitor unit as an example of an electronic apparatus that includes the flexible wiring unit;

FIGS. 6(a) and 6(b) are schematic side views showing a flexible wiring unit according to a third embodiment, and a flip down monitor unit as an example of an electronic apparatus that includes the flexible wiring unit;

FIGS. 7(a) and 7(b) are schematic side views showing a disk drive unit as an example of a conventional electronic apparatus;

FIGS. 8(a) and 8(b) are schematic side views showing a flip down monitor unit as an example of a conventional electronic apparatus;

FIG. 9(a) is a schematic transverse cross-sectional view of a flexible wiring unit according to a comparative example 1 in contact with a metal base, and FIG. 9(b) is a graph showing a simulation result of characteristic impedance of the flexible wiring unit corresponding to different line widths of a signal line, and an approximation curve thereof;

FIG. 10(a) is a schematic transverse cross-sectional view of the flexible wiring unit according to the comparative example 1, with its distal end portion spaced from the metal base, and FIG. 10(b) is a graph showing the characteristic impedance of the flexible wiring unit, corresponding to different gaps Y1;

FIG. 11(a) is a schematic transverse cross-sectional view of a flexible wiring unit according to a comparative example 2, and FIG. 11(b) is a graph showing a simulation result of the characteristic impedance of the flexible wiring unit corresponding to different line widths of the signal line, and an approximation curve thereof;

FIG. 12(a) is a schematic transverse cross-sectional view of the flexible wiring unit according to the comparative example 2 in contact with the metal base, and FIG. 12(b) is a graph showing a simulation result of the characteristic impedance of the flexible wiring unit corresponding to different line widths of the signal line, and an approximation curve thereof;

FIG. 13(a) is a schematic transverse cross-sectional view of the flexible wiring unit according to the comparative example 2, with its distal end portion spaced from the metal base, and FIG. 13(b) is a graph showing the characteristic impedance of the flexible wiring unit, corresponding to different gaps Y2;

FIG. 14(a) is a schematic transverse cross-sectional view of a flexible wiring unit according to a working example 1 in contact with the metal base, and FIG. 14(b) is a graph showing a simulation result of the characteristic impedance of the flexible wiring unit corresponding to different line widths of the signal line, and an approximation curve thereof;

FIG. 15(a) is a schematic transverse cross-sectional view of the flexible wiring unit according to the working example 1, with its distal end portion spaced from the metal base, and FIG. 15(b) is a graph showing the characteristic impedance of the flexible wiring unit, corresponding to different gaps Y3;

FIG. 16 is an enlarged graph of FIG. 13(b); and

FIG. 17(a) is a schematic transverse cross-sectional view of a flexible wiring unit according to a working example 2 in contact with the metal base, and FIG. 17(b) is a graph showing a simulation result of the characteristic impedance of the flexible wiring unit corresponding to different thicknesses of a substrate spacer, and an approximation curve thereof.

### BEST MODE FOR CARRYING OUT THE INVENTION

Hereunder, embodiments of the present invention will be described in details referring to the drawings. Description will not be repeated, where appropriate, on the same constituents as those used in the foregoing conventional flexible wiring unit and the disk drive unit or flip down monitor unit including the flexible wiring unit.

### First Embodiment

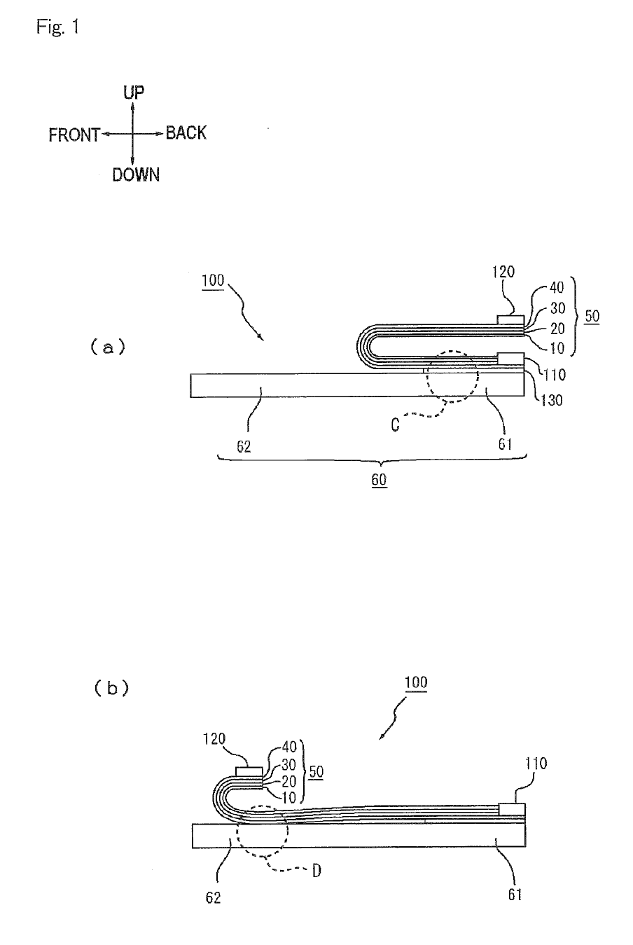

FIGS. 1(a) and 1(b) are schematic side views showing a flexible wiring unit 100 according to a first embodiment of the present invention.

First, general description will be given on the flexible wiring unit 100 according to this embodiment.

The flexible wiring unit 100 according to this embodiment includes a flexible substrate 50 that includes a signal line 30 for transmission and reception of signals to and from an external circuit (not shown), a front insulating layer 20 and a back insulating layer 40 holding the signal line 30 therebetween, a conductive shield layer 10 formed on the upper face of the front insulating layer 20 so as to cover at least a part of the signal line 30. The flexible substrate 50 has flexibility at least in a longitudinal direction.

The flexible wiring unit 100 also includes a non-conductive substrate spacer 62 provided so as to oppose the lower face of the back insulating layer 40, and a support member 61 that sustains a longitudinal end portion of the flexible substrate 50, and the other longitudinal end portion of the flexible substrate 50 is movably disposed.

A feature of the flexible wiring unit 100 is that a distance Y between the back face of the substrate spacer 62 and the signal line 30 in a state where the flexible substrate is in contact with the surface of the substrate spacer 62 is longer than a distance X between the lower face of the shield layer 10 and the signal line 30.

The flexible wiring unit 100 is a unitized wiring assembly that essentially includes the flexible substrate 50 including the signal line 30.

The flexible wiring unit 100 according to this embodiment is to be used inside an electronic apparatus, for electrically connecting electronic components exemplified by a circuit substrate and a connector.

The flexible substrate 50 is constituted of the shield layer 10, the front insulating layer 20, the signal line 30, and the back insulating layer 40, stacked on each other in this order.

In this embodiment, the side where the substrate spacer 62 is located so as to oppose the flexible substrate 50 will be referred to as the lower face side, and the opposite side as the upper face side.

The back insulating layer 40 is constituted of a combination of a base film made of an insulative material such as polyimide, and an adhesive layer that bonds the base film and the lower face of the signal line 30. It is preferable that the back insulating layer 40 has a thickness of 5 to 50 μm, from the viewpoint of effectively suppressing fluctuation in characteristic impedance arising from movement of a distal portion of the flexible substrate 50. From the viewpoint of securing appropriate bendability of the flexible substrate 50, it is preferable that the back insulating layer 40 has a thickness of 5 to 35 μm.

The signal line 30 is a wiring pattern constituted of a metal foil such as copper, having a thickness of approx. 1 to 50 μm. In this embodiment, the signal line 30 is formed in a single layer.

The front insulating layer 20 is constituted of, like the back insulating layer 40, a combination of a base film made of an insulative material and an adhesive layer that bonds the base film and the upper face of the signal line 30. It is preferable that the front insulating layer 20 has a thickness within ±30%, more preferably within ±10% of the thickness of the back insulating layer 40, from the viewpoint of securing appropriate bendability of the flexible substrate 50.

The shield layer 10 may be formed, for example, by vacuum-depositing a metal such as copper, nickel, or silver in a layer or two, on a resin film having a thickness of approx. 10 to 20 μm. Alternatively, a conductive material may be applied by a printing method, or a conductive film may be adhered, to the front insulating layer 20 or another resin film.

It is to be noted that in the present invention the shield layer 10 means a conductive layer. Accordingly, in the case where a non-conductive adhesive layer for bonding the insulative film constituting the front insulating layer 20 and the conductive layer is interleaved therebetween, or where another insulating layer exemplified by a cover layer for the conductive layer is interleaved, such insulating layer will not be construed as a part of the shield layer 10. In other words, the thickness of such insulating layer will be included in the distance X between the lower face of the shield layer 10 and the signal line 30.

The shield layer 10 also serves as a ground layer of the signal line 30. The shield layer 10 is grounded through the connector 110, to thereby protect the signal line 30 from an electromagnetic noise intruding from outside and suppress the electromagnetic noise outwardly emitted from the flexible substrate 50.

The flexible substrate 50 includes a head unit 120 attached to a distal end portion, and the connector 110 attached to a base portion. A region on the base portion side of the flexible substrate 50 is adhered by means of an adhesive layer 130 to the support member 61 over a predetermined length, together with the connector 110. On the other hand, the head unit 120 is driven back and forth by a head moving mechanism (not shown). In other words, the distal end portion of the flexible substrate 50 is movable because of the head moving mechanism.

In this embodiment, the support member 61 and the substrate spacer 62 are integrally formed, so as to constitute a plate member 60 of a single piece. It is not necessary to clearly define a boundary between the support member 61 and the substrate spacer 62, and a region where the adhesive layer 130 is provided may be called the support member 61, and a region extending forward therefrom the substrate spacer 62.

The support member 61 and the substrate spacer 62 are constituted of a non-conductive material. From the view point of low conductivity, durability, and processability, it is preferable to employ a resin such as PET, polyimide, or glass epoxy. The support member 61 and the substrate spacer 62 may be constituted of the same material or a dissimilar material.

FIG. 1(a) depicts a state where the head unit 120 has moved backward, i.e. to the right in the drawing, to a position right above the connector 110. The flexible substrate 50 assumes a horizontal U-shape because of its flexibility and rigidity balanced with each other, and an intermediate portion in the longitudinal direction is retained above the substrate spacer 62 with a spacing therefrom.

FIG. 1(b) depicts a state where the head unit 120 has moved forward, away from the connector 110 and the position above the support member 61. Since the distal end portion and the base portion of the flexible substrate 50 are deviated in the back-and-forth direction, the flexible substrate 50 is deformed into a J-shape from the U-shape. Under such state, the intermediate portion of the flexible substrate 50 is pressed downward as described earlier, because of its bending rigidity, so that the back face of the flexible substrate 50, in other words the lower face of the back insulating layer 40 enters into contact with the surface of the plate member 60.

Thus, the flexible substrate 50 enters into contact with, and gets separated from, the surface of the substrate spacer 62, according to the movement of the distal end portion of the flexible substrate 50, where the head unit 120 is provided.

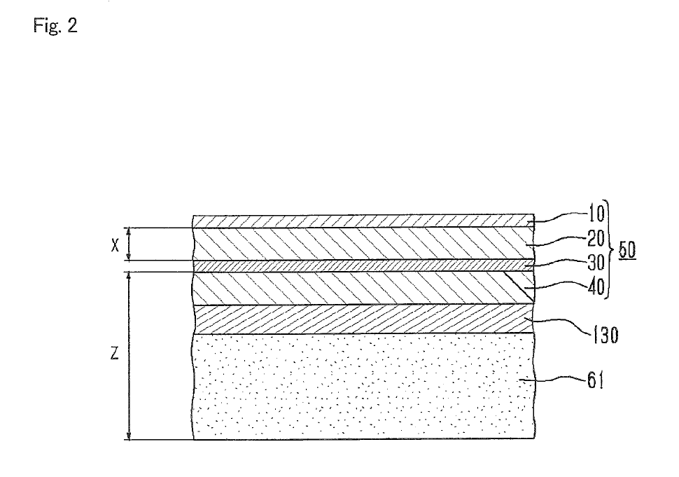

FIG. 2 is an enlarged drawing of the base portion of the flexible substrate 50 sustained by the support member 61 (region C indicated by broken lines in FIG. 1(a)).

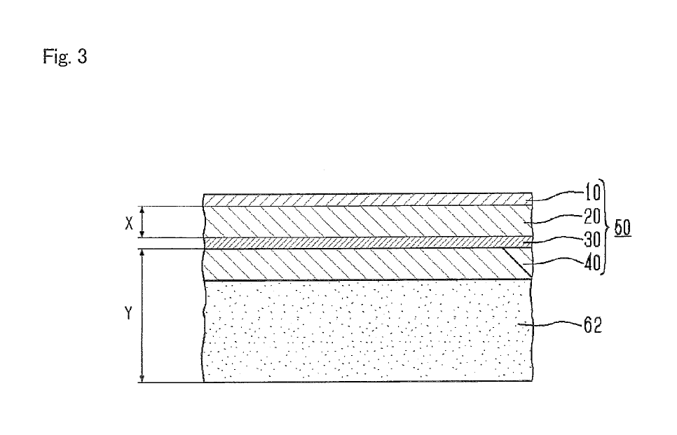

FIG. 3 is an enlarged drawing of a forward region of the flexible wiring unit 100 (region D indicated by broken lines in FIG. 1(b)), in the state where the flexible substrate 50 and the substrate spacer 62 are in mutual contact.

In the flexible wiring unit 100 according to this embodiment, the distance Y between the back face of the substrate spacer 62 and the signal line 30 in the state where the flexible substrate 50 is in contact with the surface of the substrate spacer 62 is longer than the distance X between the lower face of the shield layer 10 and the signal line 30.

As shown in FIG. 3, the distance Y between the back face of the substrate spacer 62 and the signal line 30 in the state where the flexible substrate 50 is in contact with the substrate spacer 62 corresponds, in this embodiment, to the total thickness of the back insulating layer 40 and the substrate spacer 62.

The thicknesswise distance X between the signal line 30 and the shield layer 10 corresponds to the thickness of the front insulating layer 20, in this embodiment.

Here, another layer may be provided between the signal line 30 and the back insulating layer 40, or on the lower face of the back insulating layer 40, instead of the structure according to this embodiment In this case, the thickness of such another layer will be included in the distance Y.

Likewise, in the case where another layer is provided between the signal line 30 and the front insulating layer 20, or between the front insulating layer 20 and the shield layer 10, the thickness of such another layer will be included in the distance X.

The flexible substrate 50 according to this embodiment does not include another conductive layer between the signal line 30 and the substrate spacer 62. Accordingly, the flexible substrate 50 is of a single layer structure in which the signal line 30 is provided in a single layer.

Now, according to the studies pursued by the present inventor, it has proved that making the distance Y longer than the distance X allows effectively suppressing the fluctuation in characteristic impedance Z₀ of the flexible wiring unit 100. It has further proved that making the distance Y preferably three times or more, and more preferably five times or more as long as the distance X enables even more prominently suppressing the fluctuation in characteristic impedance Z₀.

Also, as shown in FIG. 2, a distance Z between the back face of the support member 61 and the signal line 30 corresponds, in this embodiment, to the total thickness of the back insulating layer 40, the adhesive layer 130, and the support member 61.

In the flexible wiring unit 100 according to this embodiment, the support member 61 is non-conductive, and the distance Z between the back face of the support member 61 and the signal line 30 is three times or more as long as the distance X between the signal line 30 and the lower face of the shield layer 10.

Setting the distance Z three times or more as long as the distance X allows suppressing the fluctuation in characteristic impedance, in the case where the flexible substrate 50 is incorporated in an electronic apparatus such as a disk drive unit or a flip down monitor unit. Accordingly, high-quality transmission and reception of signals can be executed through the flexible wiring unit 100.

Meanwhile, the flexible wiring unit 100 is individually subjected in advance to adjustment to a predetermined characteristic impedance Z₀ (impedance control), in accordance with the electronic apparatus in which the flexible wiring unit 100 is to be incorporated. Besides, the fluctuation in characteristic impedance Z₀ of the flexible wiring unit 100 according to this embodiment can be suppressed when incorporated in the electronic apparatus. Therefore, the flexible wiring unit 100 according to this embodiment can maintain the individually adjusted characteristic impedance Z₀, irrespective of whether the base member to which the flexible wiring unit 100 is attached is a metal or non-metal.

Consequently, the flexible wiring unit 100 according to this embodiment can prevent impedance unmatching between the flexible substrate 50 and the electronic apparatus, thereby suppressing degradation in S/N ratio due to a turbulent waveform of the signal being transmitted.

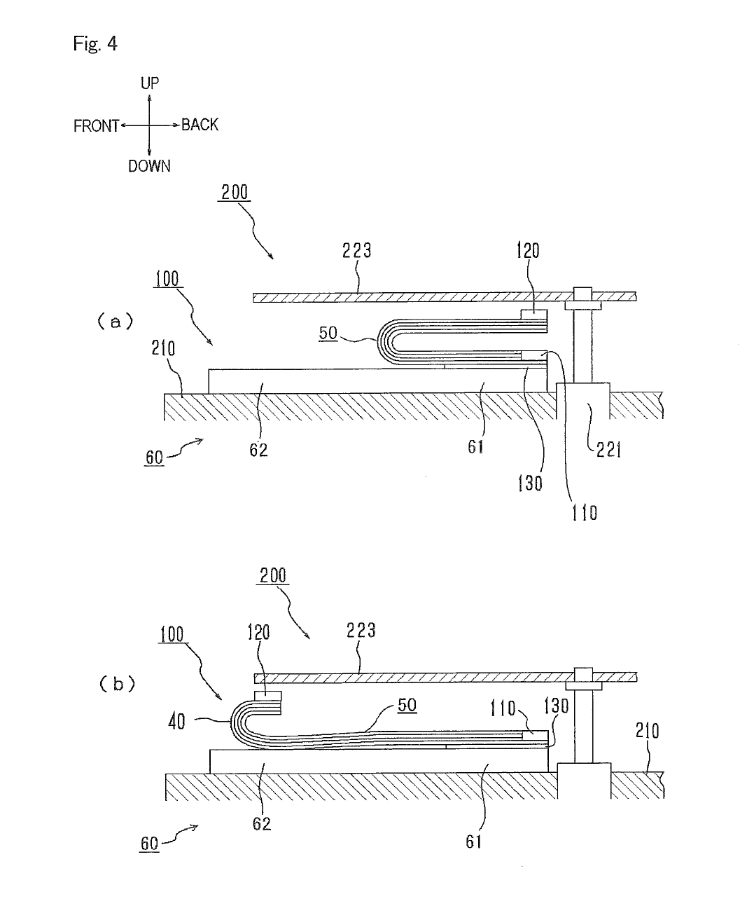

FIGS. 4(a) and 4(b) are schematic side views showing a disk drive unit 200 as an example of the electronic apparatus in which the flexible wiring unit 100 according to this embodiment is mounted on a metal base 210.

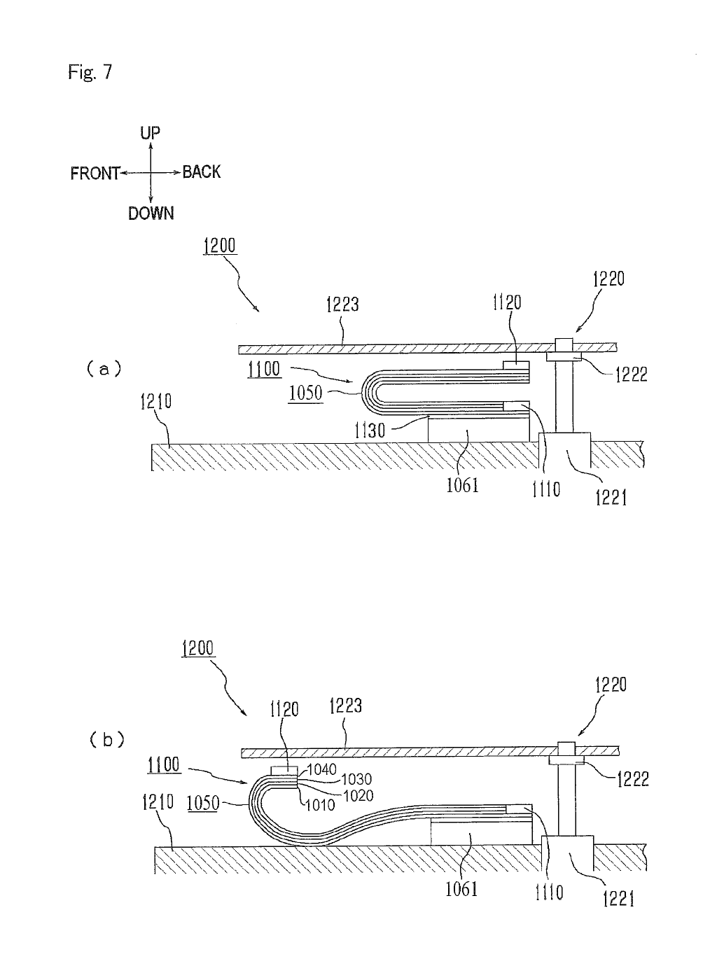

The structure of the disk drive unit 200 is the same as that of the conventional disk drive unit 1200 shown in FIGS. 7(a) and 7(b) except for the flexible wiring unit 100, and hence the description thereof will not be repeated.

The shape of the metal base 210 according to this embodiment is not specifically limited. The metal base 210 may be of a flat plate shape as in this embodiment, or may have an uneven surface as in a second and a third embodiment to be subsequently described. The surface of a region of the metal base 210 where the flexible wiring unit 100 is mounted may be either conductive or coated with an insulative film or paint.

FIG. 4(a) depicts a state where the head unit 120 is making access to a track in an inner region of a disk 223 to be driven to rotate by a driving motor 221. The flexible substrate 50 bent in the U-shape is not in contact with the substrate spacer 62.

FIG. 4(b) depicts a state where the head unit 120 has moved forward to make access to a track in an outer region of the disk 223. The flexible substrate 50 is deformed in the J-shape, such that the back insulating layer 40, constituting the lower face thereof, is in contact with the substrate spacer 62.

Even in such state, the flexible substrate 50 is kept from contacting the metal base 210, and the signal line 30 is spaced from the metal base 210 by the distance Y (Ref. FIG. 3).

In the case where the head unit 120 again makes access to the track in the inner region of the disk 223, the flexible substrate 50 returns to the U-shape and the flexible substrate 50 gets spaced from the substrate spacer 62.

During such action, the base portion of the flexible substrate 50 is fixed to the metal base 210 via the adhesive layer 130 and the support member 61.

Description will now be given on advantageous effects of the flexible wiring unit 100 according to this embodiment and the disk drive unit 200 including the flexible wiring unit 100.

First, providing the non-conductive substrate spacer 62 so as to oppose the lower face of the signal line 30 allows preventing the back face of the flexible substrate 50 from contacting the metal base 210, despite mounting the flexible wiring unit 100 on the metal base 210. Thus, the thickness of the substrate spacer 62 contributes to securing a sufficiently long distance between the metal base 210 and the signal line 30.

Here, a primary reason of the fluctuation in characteristic impedance Z₀ of the flexible wiring unit 100 is, as stated above, fluctuation in static capacitance between the signal line 30 and the metal base 210 on which the signal line 30 is provided. Now, in the case of this embodiment in which no other conductive layer is provided between the signal line 30 and the substrate spacer 62 as stated above, the static capacitance is approximately inversely proportional to the square of the distance Y between the signal line 30 and the substrate spacer 62. Accordingly, increasing the distance Y leads to reducing the static capacitance itself, thereby suppressing the fluctuation of the static capacitance.

Therefore, even though the distal end portion of the flexible substrate 50 is moved so that the front-to-back length thereof opposing the metal base 210 fluctuates, or so that the lower face of the flexible substrate 50 is pressed against the substrate spacer 62, the fluctuation in characteristic impedance Z₀ of the flexible wiring unit 100 can be suppressed.

Also, reducing the distance X between the signal line 30 and the shield layer 10 allows stabilizing the signal level of the signal line 30, especially in the case where, as in this embodiment, the shield layer 10 serves as a ground layer earthed to the ground level.

Such configuration allows further suppressing the fluctuation in characteristic impedance Z₀ of the flexible wiring unit 100.

Accordingly, it is preferable to make the distance Y longer than the distance X as stated above, and the distance X, Y can serve as predominant parameters for suppressing the fluctuation in characteristic impedance Z₀ of the flexible wiring unit 100.

Here, making the distance Y three times or more as long as the distance X further assures the suppressing effect of the fluctuation in characteristic impedance Z₀ of the flexible wiring unit 100, in the case where the shield layer 10 serves as the ground layer as in this embodiment. Further, making the distance Y five times or more as long as the distance X allows sufficiently suppressing the fluctuation in characteristic impedance Z₀ of the flexible wiring unit 100, even in the case where the shield layer 10 is not grounded through the connector 110.

In the flexible substrate 50 the signal line 30 is provided in a single layer, and the shield layer 10 is only provided on the upper face, and not on the lower face. Such structure enables making the flexible substrate 50 thinner, thereby attaining sufficient bendability.

Since the shield layer 10 is provided on the upper face of the flexible substrate 50, the shield layer 10 can be easily connected to the connector 110 for achieving electrical contact. In the flexible wiring unit 100, also, the shield layer 10 provided on the upper face serves to block the electromagnetic wave predominantly emitted from the head unit 120, thereby suppressing impact of the electromagnetic noise on the signal line 30.

In the case of a one-sided Flexible Printed Circuit (FPC) including the single-layer signal line 30, which is typical of the flexible substrate 50, it is preferable to locate a connector pad and a contact pad on the same face of the flexible substrate 50. Such structure facilitates the processing of the flexible substrate 50.

Here, the connector pad is a pad-type connector provided on the flexible substrate 50 for electrical connection between the signal line 30 and the connector 110. The contact pad is a pad-type connector provided on the flexible substrate 50 for connecting the signal line 30 to the shield layer 10, which serves as the ground for the signal line 30.

In this embodiment, thus, providing both the shield layer 10 and the connector 110 on the upper face side of the signal line 30, and the substrate spacer 62 on the lower face side, allows attaining both the processability of the flexible substrate 50 and the suppression effect of the fluctuation in characteristic impedance Z₀ of the flexible wiring unit 100.

If the shield layer 10 were provided only on the lower face side of the flexible substrate 50, the signal line 30 would be exposed to the electromagnetic wave and the shielding effect would become limited, which would make it difficult to suppress the impact of the electromagnetic noise. Also, if the shield layer 10 were provided on both sides of the flexible substrate 50, the line width of the signal line 30 would have to be made quite fine, for executing the impedance control of the flexible wiring unit 100.

In contrast, providing the shield layer 10 only on the upper face side of the flexible substrate 50 as in this embodiment can minimize such drawbacks.

In the case of a double-sided FPC, which includes two layers of signal line 30 with an insulating layer interleaved therebetween, and a connector pad located on either side of the insulating layer, a via penetrating through the insulating layer may be formed for achieving connection between the connector pad and the signal line 30 on the other side. Such structure enables electrically connecting the signal line 30 on the respective sides of the insulating layer to the connector pad. It should be noted that, whereas it is known that the via is generally prone to degrade the electrical characteristic of the flexible substrate 50, employing the single-layer signal line 30 as in this embodiment eliminates such drawback.

The conventional flexible wiring unit has a drawback that, in the case where a conductive layer such as the shield layer cannot be provided on the lower face of the flexible substrate 50, the fluctuation in characteristic impedance Z₀ of the flexible wiring unit 100 is incurred depending on the positional relationship between the flexible substrate 50 and the metal base 210 on which the flexible substrate 50 is provided. In contrast, in the flexible wiring unit 100 according to this embodiment, the substrate spacer 62 is located so as to oppose the lower face of the back insulating layer 40, and the proportion of the distance X and the distance Y is specified as above, and therefore the fluctuation in characteristic impedance Z₀ can be suppressed, and further the single-layer structure of the signal line 30 provides the foregoing advantages.

Further, in the flexible wiring unit 100 according to this embodiment, the support member 61 and the substrate spacer 62 are integrally formed. Such structure improves the productivity of these components and facilitates the positioning of the flexible wiring unit 100 in the mounting process thereof.

### Second Embodiment

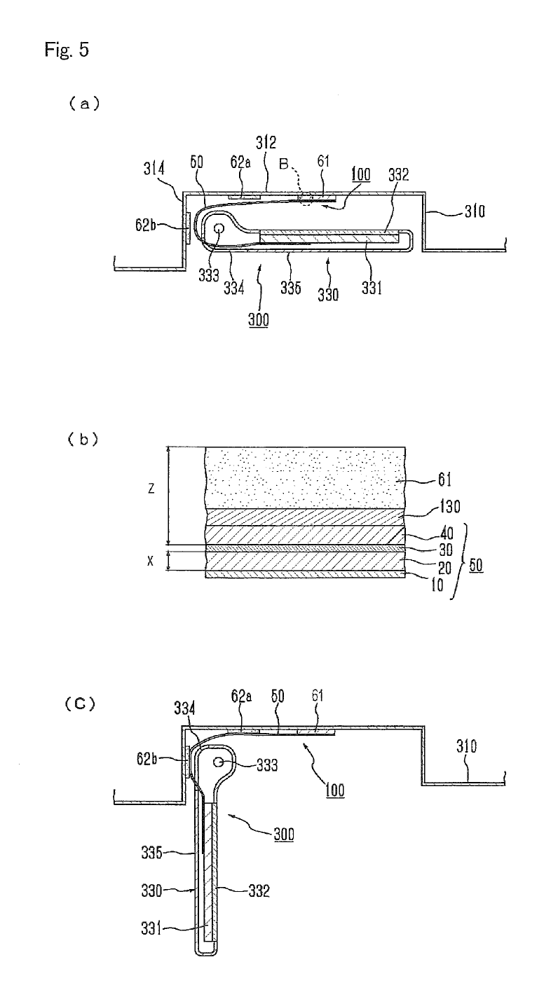

FIGS. 5(a) to 5(c) are schematic side views showing the flexible wiring unit 100 according to a second embodiment of the present invention, and a flip down monitor unit 300 as an example of the electronic apparatus that includes the flexible wiring unit 100 mounted on a metal base 310.

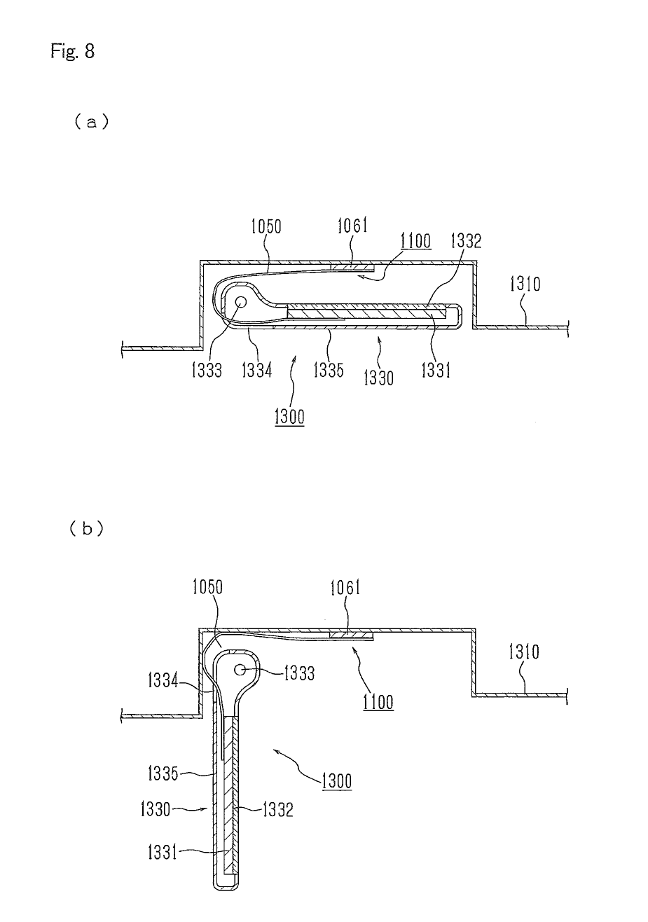

The structure of the flip down monitor unit 300 is the same as that of the conventional flip down monitor unit 1300 shown in FIGS. 8(a) and 8(b) except for the flexible wiring unit 100, and hence the description thereof will not be repeated.

FIG. 5(a) depicts a state where a monitor 330 is stored in the metal base 310.

FIG. 5(b) is an enlarged drawing of a region B indicated by broken lines in FIG. 5(a), showing the flexible substrate 50 and the support member 61 sustaining the flexible substrate 50. The metal base 310 is not included in FIG. 5(b).

FIG. 5(c) depicts a state where the monitor 330 has been rotated clockwise about a hinge 333, so that the display screen 332 is exposed.

In this embodiment also, in the base portion of the flexible substrate 50 sustained by the support member 61, the distance Z between the back face of the support member 61 (upper side in FIG. 5(b)) and the signal line 30 is three times or more as long as the distance X between the signal line 30 and the lower face of the shield layer 10 (upper side in FIG. 5(b)).

Such configuration effectively suppresses initial fall in characteristic impedance Z₀ due to the mounting of the flexible wiring unit 100 on the metal base 310.

A feature of the flexible wiring unit 100 according to this embodiment is that two substrate spacers 62 (substrate spacer 62a, 62b) are provided on the metal base 310.

More particularly, the substrate spacer 62a is located on a ceiling face 312 of the metal base 310, on which the support member 61 for fixing the base portion of the flexible substrate 50 is mounted. The substrate spacer 62b is located on a vertical wall 314 of the metal base 310, to which a driver circuit 331 comes close when the display screen 332 is exposed. According to the present invention, a plurality of substrate spacers 62 may thus be provided.

As shown in FIG. 5(a), while the monitor 330 is stored the flexible substrate 50 bent in a U-shape is not in contact with the substrate spacer 62a, 62b.

Then as shown in FIG. 5(c), when the monitor 330 is opened the flexible substrate 50 led out through the wiring slot 334 is deformed in an L-shape, and swells away from a metal housing 335 thus to be pressed against the substrate spacer 62a, 62b.

Even under such state, in the flexible wiring unit 100 according to this embodiment the non-conductive substrate spacers 62a, 62b provided so as to confront the lower face of the back insulating layer 40 keep the flexible substrate 50 from contacting the metal base 310. Also, the signal line 30 is spaced from the metal base 310 by the distance Y (Ref. FIG. 3).

Such structure allows suppressing the fluctuation in characteristic impedance Z₀ of the flexible wiring unit 100 arising from the opening and closing action of the monitor 330, thereby assuring high-quality transmission of output signals to the display screen 332 through the flexible wiring unit 100.

It is to be noted that in this embodiment the lower face side of the flexible substrate 50 means the side closer to the metal base 310, and not the upper or lower side in the gravity direction.

Dividing thus the substrate spacer 62 into a plurality of members allows keeping the flexible substrate 50 from contacting the metal base 310, in the case of mounting the flexible wiring unit 100 according to this embodiment on the metal base 310 of a different shape from the flat plate. With such configuration, the flexible wiring unit 100 according to this embodiment can suppress the fluctuation in characteristic impedance Z₀.

As a modification of this embodiment, the vertical wall 314 may be curved so as to be spaced from the hinge 333, so that the flexible substrate 50 is kept from contacting the vertical wall 314 when the monitor 330 is opened (Ref. FIG. 5(c)). Such configuration eliminates the need to employ the substrate spacer 62b which serves to prevent the flexible substrate 50 from contacting the vertical wall 314.

### Third Embodiment

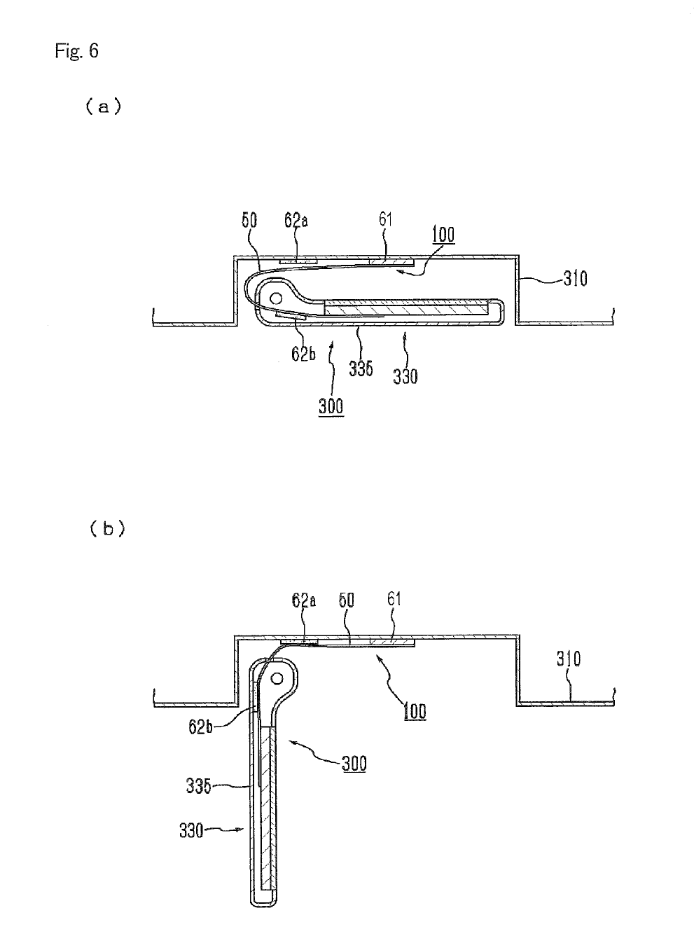

FIGS. 6(a) and 6(b) are schematic side views showing the flexible wiring unit 100 according to a third embodiment of the present invention, and the flip down monitor unit 300 including the flexible wiring unit 100. Description will not be repeated on the portions that are same as those of the second embodiment.

In the flexible wiring unit 100 according to this embodiment, one of the plurality of substrate spacers 62 which is divided (substrate spacer 62b) is attached to the lower face of the flexible substrate 50, so that the flexible substrate 50 and the substrate spacer 62b can move interlockedly.

FIG. 6(a) depicts a state where the monitor 330 is stored. The back face of the substrate spacer 62b is not in contact with the metal housing 335. Also, the substrate spacer 62a attached to the ceiling of the metal base 310 is not in contact with the flexible substrate 50.

FIG. 6(b) depicts a state where the monitor 330 is opened. The back face of the substrate spacer 62b is in contact with the metal housing 335. The substrate spacer 62a and the flexible substrate 50 are also in mutual contact.

The substrate spacers 62a, 62b according to this embodiment are also constituted of a non-conductive material, as in the first and the second embodiment. Also, the distance Y between the back face of the substrate spacer 62a, 62b and the signal line 30 in the flexible substrate 50 (Ref. FIG. 3) is longer than the distance X between the signal line 30 and the shield layer 10 (Ref. FIG. 3).

In this embodiment, the substrate spacer 62b serves to suppress the fluctuation in static capacitance between the metal housing 335 and the signal line 30, and the substrate spacer 62a serves to suppress the fluctuation in static capacitance between the metal base 310 and the signal line 30.

Thus, providing the plurality of substrate spacers 62 as in this embodiment allows also suppressing the fluctuation in static capacitance between the flexible substrate 50 and the metal housing 335, which is a component of a different metal from the metal base 310.

Also, attaching a part or the whole of the substrate spacer 62 to the back face of the flexible substrate 50 thus unifying them as in this embodiment makes it easier to handle the flexible wiring unit 100. Further, the fluctuation in characteristic impedance Z₀ of the flexible wiring unit 100 can be suppressed, even in the case where it is difficult to fixedly attach the substrate spacer 62 to a metal component, for example the inner surface of the metal housing 335.

It is to be understood that the present invention is not limited to the foregoing embodiments, but various modifications may be made within the scope of the present invention.

First, the disk drive unit 200 and the flip down monitor unit 300 are merely an example of the electronic apparatuses in which the flexible wiring unit 100 can be incorporated. Other examples of the electronic apparatus include those having a metal base and a movable portion, such as a printer head, a clam-shell type mobile phone and laptop computer, a robot, a transport apparatus, and so forth.

Focusing on the clam-shell type mobile phone, the opening and closing action is repeatedly made day by day, and the action speed is as quick as approx. one second. Accordingly, in the case of the clam-shell type mobile phone, the advantage of the present invention that the fluctuation in characteristic impedance Z₀, arising from the contact/non-contact repetition between the flexible substrate 50 and the metal base is suppressed can be particularly prominently enjoyed. Especially in the case of lately developed clam-shell type mobile phones, an extensive variety of functions such as camera, music reproduction, and phone conversation are often utilized irrespective of whether the mobile phone is open or closed. The advantage of the present invention appears even more prominently in such mobile phones, because a difference in characteristic impedance Z₀ between the closed and open states is suppressed. In addition, the deformation pattern of the flexible substrate 50 is not limited to the U-shape, J-shape, and L-shape.

When applying the flexible wiring unit 100 according to the present invention to those electronic apparatuses, it is preferable, whichever the apparatus may be, to make the distance Y between the surface of the metal base and the signal line three times or more as long, more preferably five times or more as long as the distance X between the lower face of the shield layer and the signal line.

In the respective embodiments, the flexible substrate 50 is spaced from the substrate spacer 62 in some cases (FIG. 4(a), FIG. 5(a), FIG. 6(a)), and in contact therewith in other cases (FIG. 4(b), FIG. 5(b) FIG. 6(b)). In the present invention, however, the flexible substrate 50 and the substrate spacer 62 may be constantly spaced from each other or in mutual contact. In other words, the flexible substrate 50 and the metal base 210, 310 may be constantly spaced from each other with the substrate spacer 62 and an optional intermediate layer provided therebetween, or the entirety thereof may be continuously stacked constantly.

Although the signal line 30 is of the single-layer structure in the foregoing embodiments, the flexible substrate 50 may include a plurality of layers of signal line 30.

In this case, the distance Y between the signal line 30 and the back face of the substrate spacer 62, and the distance Z between the signal line 30 and the back face of the support member 61 are to be taken from the signal line 30 in a closest layer to the lower face, to the substrate spacer 62 or the support member 61. On the other hand, the distance X between the signal line 30 and the lower face of the shield layer 10 is to be taken from the signal line 30 in a closest layer to the upper face, to the lower face of the shield layer 10.

The foregoing embodiments of the present invention encompass the following technical idea.

(1) A flexible wiring unit comprising: a flexible substrate having flexibility in a longitudinal direction, including a signal line used for transmitting and receiving a signal to and from an external circuit, a front insulating layer and a back insulating layer with the signal line interleaved therebetween, and a conductive shield layer provided on an upper face of the front insulating layer so as to cover at least a part of the signal line;

a non-conductive substrate spacer provided so as to oppose a lower face of the back insulating layer;

a support member that sustains a longitudinal end portion of the flexible substrate;

the other longitudinal end portion of the flexible substrate being movably disposed;

wherein a distance Z between a back face of the support member and the signal line is three times or more as long as a distance X between the signal line and a lower face of the shield layer.

(2) The flexible wiring unit according to (1) above, wherein a distance Y between a back face of the substrate spacer and the signal line in a state where the flexible substrate is in contact with a surface of the substrate spacer is longer than a distance X between a lower face of the shield layer and the signal line.

(3) The flexible wiring unit according to (2) above, wherein the distance Y is three times or more as long as the distance X.

(4) The flexible wiring unit according to any of (1) to (3) above, wherein the support member and the substrate spacer are integrally formed.

(5) The flexible wiring unit according to any of (1) to (4) above, wherein the flexible substrate does not include a conductive layer between the signal line and the support member.

(6) An electronic apparatus, comprising:

a metal base;

a flexible substrate having flexibility in a longitudinal direction, including a signal line used for transmitting and receiving a signal to and from an external circuit, a front insulating layer and a back insulating layer with the signal line interleaved therebetween, and a conductive shield layer provided on an upper face of the front insulating layer so as to cover at least a part of the signal line;

a non-conductive substrate spacer provided so as to oppose a lower face of the back insulating layer, and a support member that sustains a longitudinal end portion of the flexible substrate, both located on the metal base;

wherein the other longitudinal end portion of the flexible substrate is movably disposed; and

a distance Z between a back face of the support member and the signal line is three times or more as long as a distance X between the signal line and a lower face of the shield layer.

### WORKING EXAMPLE

With respect to the flexible wiring unit 100 according to the foregoing embodiments, simulation was executed regarding the suppression effect of the fluctuation in characteristic impedance arising from the movement of the distal end portion of the flexible wiring unit 100. Such simulation was executed for verifying that it is preferable that the distance Y is longer than the distance X, and that the distance Y is three times or more as long, more preferably five times or more as long as the distance X.

The simulation described below was executed based on the typical dimensions and material characteristics of currently available flexible wiring unit. Accordingly, in the case where further progress is made in the future in reduction in thickness of the thin film structure, micronization of the signal line, or in the electrical characteristic of materials, the preferable numerical relationship between the distance X and the distance Y may become different. However, those skilled in the art should be able to easily reach the preferable relationship between the distance X and the distance Y within the scope of the present invention, based on the characteristics and dimensions of the materials constituting the flexible wiring unit.

Hereunder, a transverse cross-section of the flexible wiring unit 100, 1100 means a section orthogonally taken with respect to a longitudinal direction of the flexible substrate 50, 1050, i.e. extending direction of the signal line 30, 1030.

The simulation result was obtained by two-dimensionally calculating the characteristic impedance Z₀ of the transverse cross-section of the flexible wiring unit 100, 1100 spaced by a predetermined distance from the metal base 210, 1210.

### Comparative Example 1

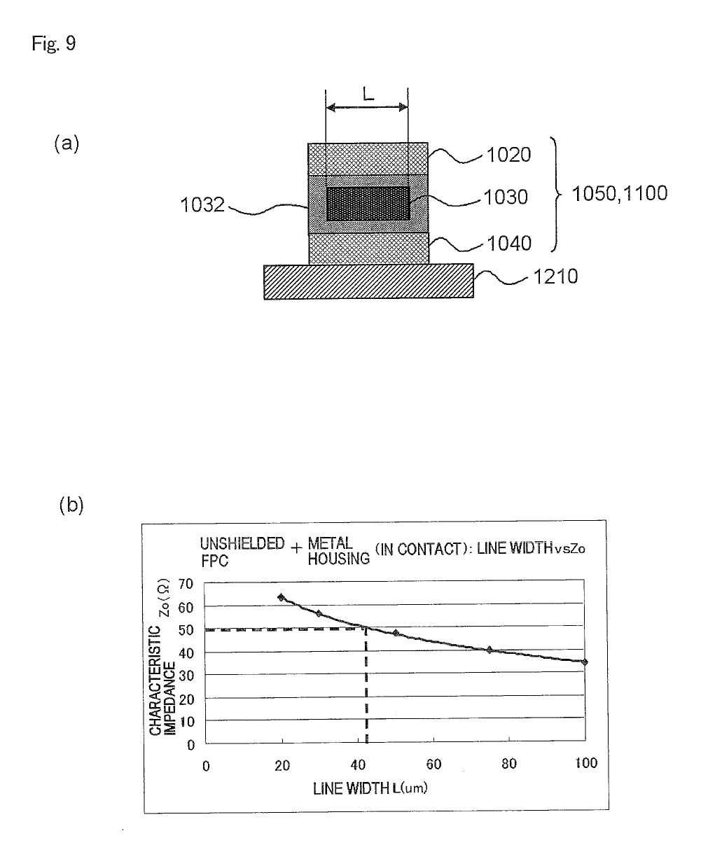

FIG. 9(a) is a schematic transverse cross-sectional view of the flexible wiring unit 1100 according to a comparative example 1, in contact with the metal base 1210.

As the signal line 1030, properties of a copper foil of 35 μm in thickness were employed. Around the signal line 1030, a non-conductive adhesive layer 1032 is provided.

As the front insulating layer 1020 (coverlay) and the back insulating layer 1040 (base film), properties of a polyimide film of 25 μm in thickness were employed respectively.

The flexible wiring unit 1100 according to this comparative example includes the flexible substrate 1050 constituted of the back insulating layer 1040, the signal line 1030, and the front insulating layer 1020 stacked in this order from below.

The thickness of the adhesive layer 1032 between the front insulating layer 1020 and the signal line 1030, and between the back insulating layer 1040 and the signal line 1030, was set as 10 μm.

As the metal base 1210, properties of a stainless steel were employed.

Also, the width of the front insulating layer 1020 and the back insulating layer 1040 was always wider than the line width of the signal line 1030.

FIG. 9(b) shows the simulation result of the characteristic impedance Z₀ of the flexible wiring unit 1100 corresponding to different line widths L of the signal line 1030 from 20 μm to 100 μm under the foregoing setting, and an approximation curve thereof. As indicated by broken lines in FIG. 9(b), the line width L that gave Z₀ of 50Ω was approx. 42 μm.

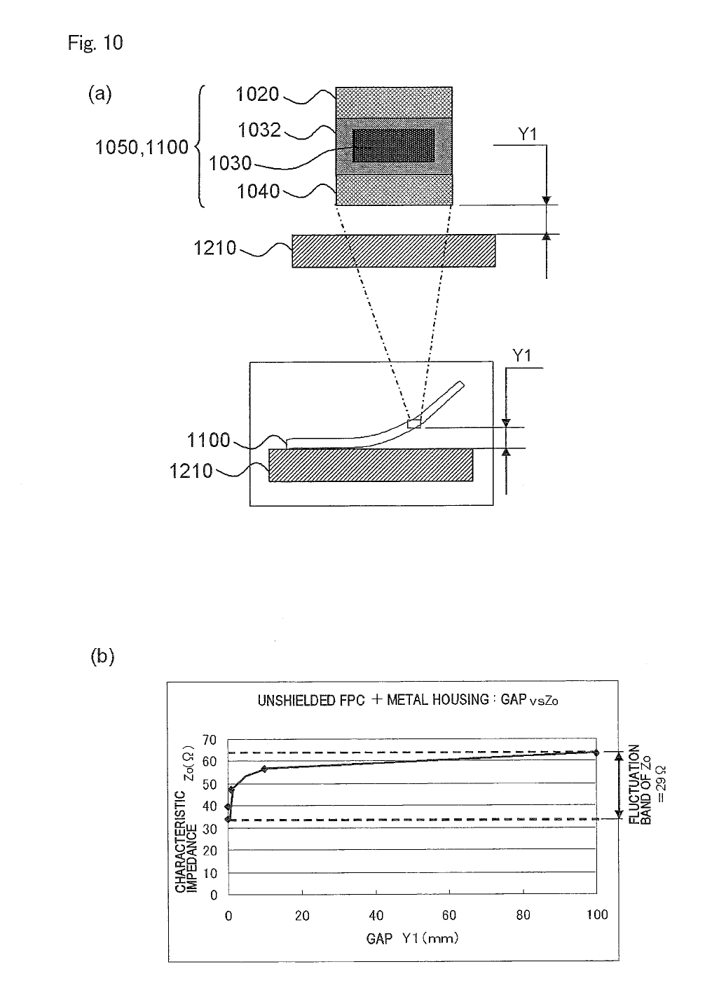

FIG. 10(a) is a schematic transverse cross-sectional view of the flexible wiring unit 1100 according to this comparative example, with its distal end portion spaced from the metal base 1210. A lower portion of FIG. 10(a) is a schematic side view of the flexible wiring unit 1100. Accordingly, an upper portion of FIG. 10(a) is an enlarged cross-sectional drawing of the lower portion of FIG. 10(a), viewed from the right.

As shown therein, a distance (gap) between the lower face of the back insulating layer 1040 and the metal base 1210 will be denoted by Y1.

FIG. 10(b) is a graph showing the characteristic impedance Z₀ of the flexible wiring unit 1100 with the line width L of the signal line 1030 set as 100 μm, corresponding to different gaps Y1 from 0 to 100 mm.

From FIG. 10(b) it is understood that the characteristic impedance Z₀ of the flexible wiring unit 1100 according to this comparative example fluctuated as much as 29Ω between the state where the flexible wiring unit 1100 is in contact with the metal base 1210 (FIG. 9(a)) and sufficiently spaced therefrom (FIG. 10(a)). Such fluctuation amount corresponds to 85% of Z₀ (34Ω) in the initial state (in contact, i.e. Y1=0 μm).

### Comparative example 2

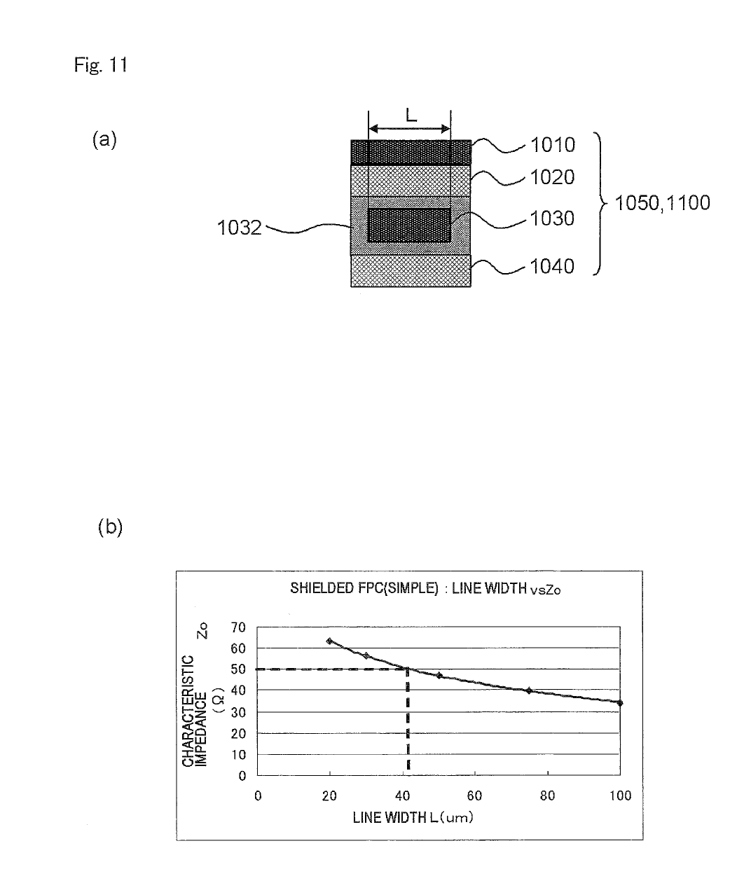

FIG. 11(a) is a schematic transverse cross-sectional view of the flexible wiring unit 1100 according to a comparative example 2. The flexible wiring unit 1100 is independent, sufficiently spaced from the metal base.

The flexible wiring unit 1100 according to this comparative example is different from that of the comparative example 1, only in that an upper shield layer 1010 is provided on the front insulating layer 1020. As the upper shield layer 1010, properties of a silver paste of 20 μm in thickness were employed.

FIG. 11(b) is a graph showing a simulation result of the characteristic impedance Z₀ of the flexible wiring unit 1100 corresponding to different line widths L of the signal line from 20 μm to 100 μm, and an approximation curve thereof.

As indicated by broken lines in FIG. 11(b), the line width L that gave Z₀ of 50Ω was approx. 42 μm.

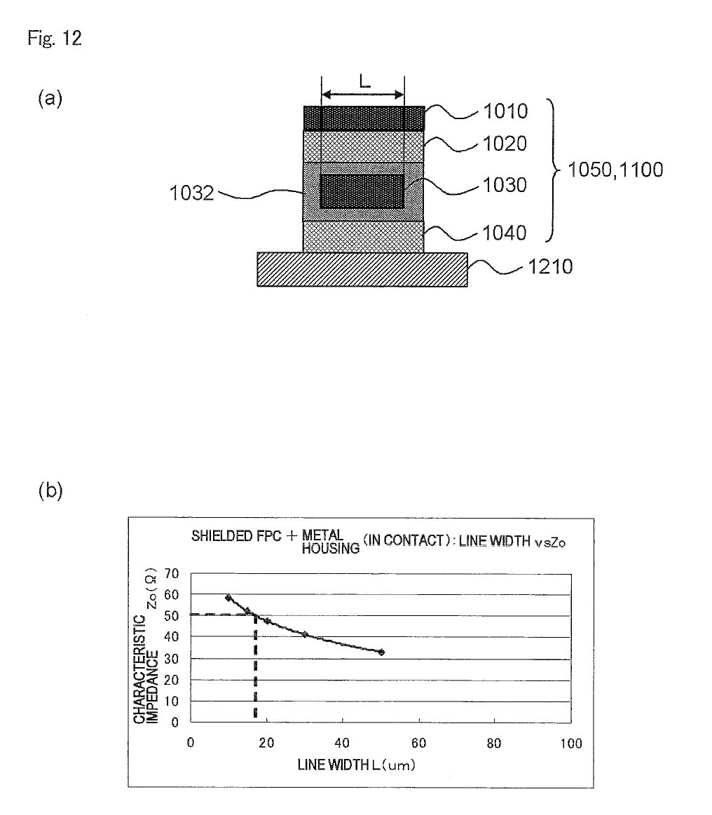

FIG. 12(a) is a schematic transverse cross-sectional view of the flexible wiring unit 1100 according to the comparative example 2, in contact with the metal base 1210.

FIG. 12(b) is a graph showing a simulation result of the characteristic impedance Z₀ of the flexible wiring unit 1100 in contact with the surface of the metal base 1210, corresponding to different line widths L of the signal line from 10 to 50 μm, and an approximation curve thereof. As indicated by broken lines in FIG. 12(b), the line width L that gave Z₀ of 50Ω was approx. 17 μm.

In comparison between FIG. 11(b) and FIG. 12(b), it is understood that the flexible wiring unit 1100 according to this comparative example incurs significant fall (initial fall) of the characteristic impedance Z₀, upon being attached to the metal base 1210.

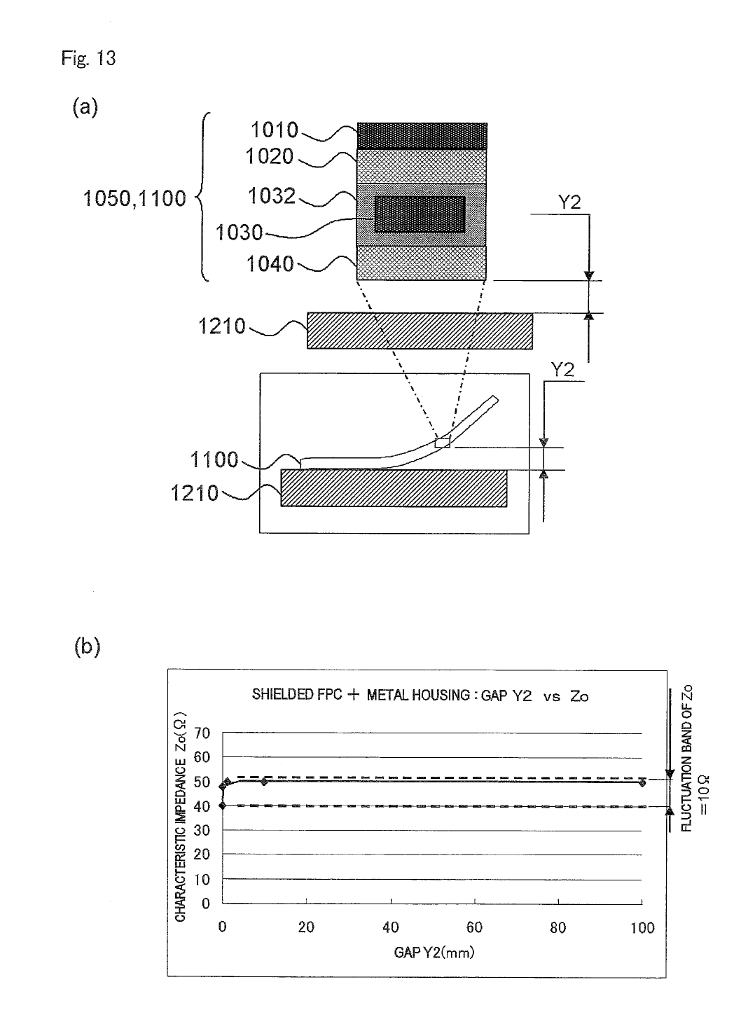

FIG. 13(a) is a schematic transverse cross-sectional view of the flexible wiring unit 1100 according to this comparative example, with its distal end portion spaced from the metal base 1210. A lower portion of FIG. 13(a) is a schematic side view of the flexible wiring unit 1100. Accordingly, an upper portion of FIG. 13(a) is an enlarged cross-sectional drawing of the lower portion of FIG. 13(a), viewed from the right.

As shown therein, a distance (gap) between the lower face of the back insulating layer 1040 and the metal base 1210 will be denoted by Y2.

FIG. 13(b) is a graph showing the characteristic impedance Z₀ of the flexible wiring unit 1100 with the line width L of the signal line 1030 set as 30 μm, corresponding to different gaps Y2 from 0 to 100 mm.

From FIG. 13(b) it is understood that the characteristic impedance Z₀ of the flexible wiring unit 1100 according to this comparative example fluctuated by 10Ω between the state where the flexible wiring unit 1100 is in contact with the metal base 1210 (FIG. 12(a)) and sufficiently spaced therefrom (FIG. 13(a)). Such fluctuation amount corresponds to 25% of Z₀ (40Ω) in the initial state (in contact, i.e. Y2=0 μm).

### Working Example 1

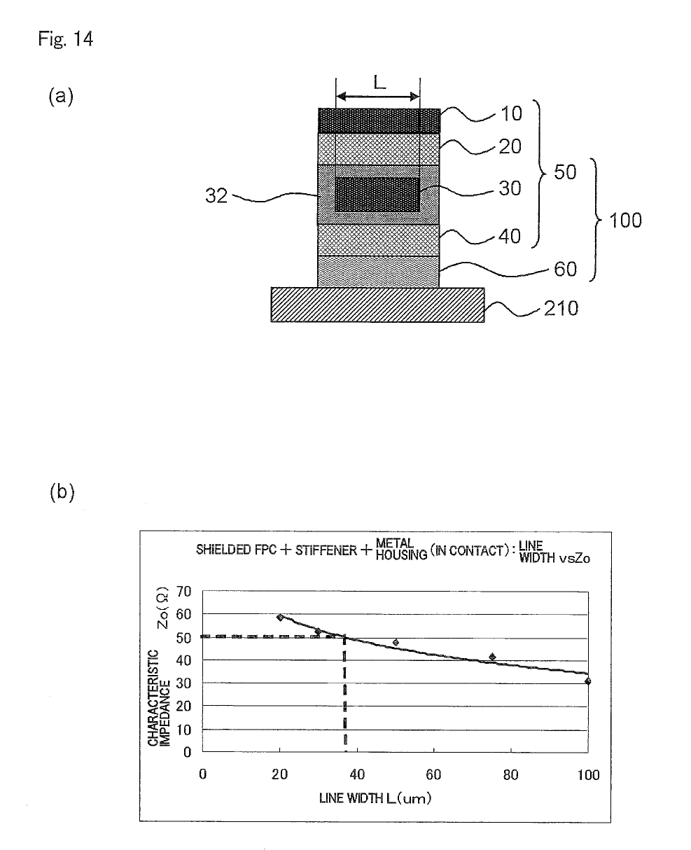

FIG. 14(a) is a schematic transverse cross-sectional view of the flexible wiring unit 100 according to a working example 1, in contact with the metal base 210.

The flexible wiring unit 100 according to this working example is different from that of the comparative example 2, only in that a plate member 60 (support member 61 and substrate spacer 62) is joined to the lower face of the back insulating layer 40, via a non-conductive adhesive layer (not shown). Hereunder, the plate member 60 may be referred to as a reinforcing plate.

As the plate member 60, properties of PET were employed. The total thickness of the plate member 60 and the non-conductive adhesive layer was set as 145 μm. Accordingly, in the flexible wiring unit 100, the distance Y between the back face of the plate member 60 and the signal line 30 was 180 μm, including the thickness of the back insulating layer 40 (25 μm) and the adhesive layer 32 (10 μm). Also, the distance X between the lower face of the shield layer 10 and the signal line 30 was 35 μm, including the thickness of the front insulating layer 20 and the adhesive layer 32. In this working example, therefore, Y is equal to Z, and nearly equal to 5X.

Here, the characteristic impedance Z₀ of the independent flexible wiring unit 100 according to this working example was similar to the case of the comparative example 2 (FIG. 11(b)).

FIG. 14(b) is a graph showing a simulation result of the characteristic impedance Z₀ of the flexible wiring unit 100 in contact with the surface of the metal base 210, corresponding to different line widths L of the signal line 30 from 20 to 100 μm, and an approximation curve thereof. As indicated by broken lines in FIG. 14(b), the line width L that gave Z₀ of 50Ω was approx. 37 μm, which is close to the characteristic impedance Z₀ of the independent flexible wiring unit 100.

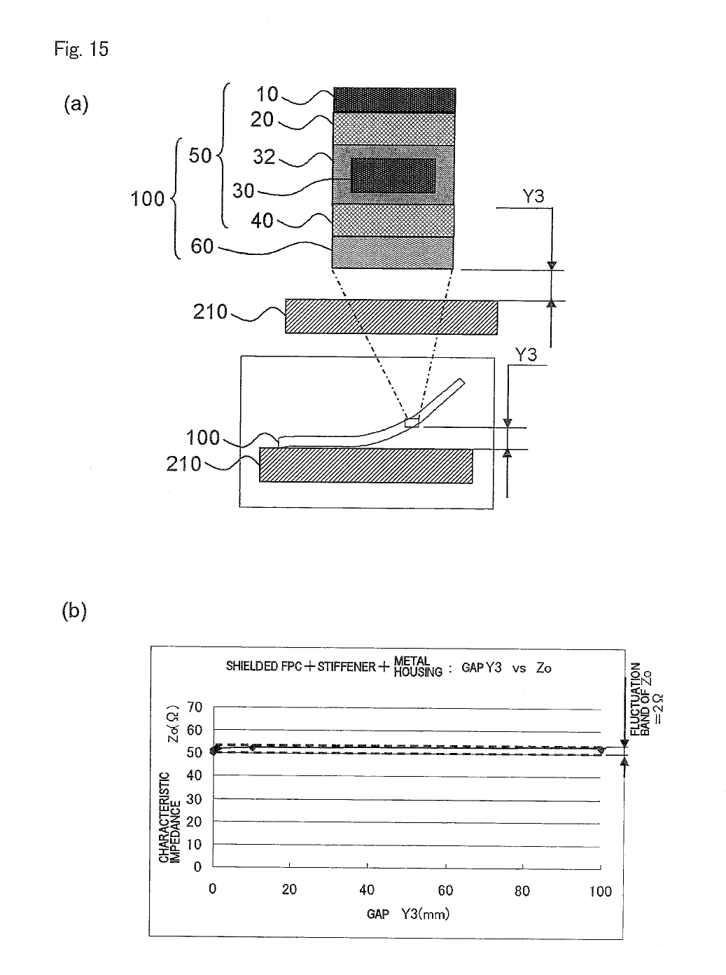

FIG. 15(a) is a schematic transverse cross-sectional view of the flexible wiring unit 100 according to this working example, with its distal end portion spaced from the metal base 210. A lower portion of FIG. 15(a) is a schematic side view of the flexible wiring unit 100. Accordingly, an upper portion of FIG. 15(a) is an enlarged cross-sectional drawing of the lower portion of FIG. 15(a), viewed from the right.

As shown therein, a distance (gap) between the lower face of the plate member 60 and the metal base 210 will be denoted by Y3.

FIG. 15(b) is a graph showing the characteristic impedance Z₀ of the flexible wiring unit 100 with the line width L of the signal line 30 set as 37 μm, corresponding to different gaps Y3 from 0 to 100 mm.

From FIG. 15(b) it is understood that the characteristic impedance Z₀ of the flexible wiring unit 100 according to this working example fluctuated by 2Ω between the state where the flexible wiring unit 100 is in contact with the metal base 210 (FIG. 14(a)) and sufficiently spaced therefrom (FIG. 15(a)). Such fluctuation amount corresponds to approx. 4% of Z₀ (50Ω) in the initial state (in contact, i.e. Y3=0 μm).

Thus, it is understood that making the distance Z three times or more as long as the distance X, by interleaving the plate member 60 between the back insulating layer 40 of the predetermined thickness and the metal base 210 according to the working example 1, has resulted in suppressing the difference in characteristic impedance Z₀ of the flexible wiring unit 100, between the state where the flexible wiring unit 100 is in contact with the metal base 210 and spaced therefrom.

Based on the comparative examples 1, 2 and the working example 1, the following findings can be obtained.

First, it is understood that providing the shield layer 1010 on the upper side of the flexible wiring unit 1100 incurs a significant fall of the characteristic impedance Z₀ of the flexible wiring unit 1100 in contact with the metal base 1210 (comparative example 1, 2). In the case of adjusting Z₀ at 50Ω for example, the line width L of the signal line 1030 has to be narrowed to 17 μm from 42 μm, which leads to degraded processability and durability.

In contrast, in the case of the working example 1, the line width L of the signal line 30 that gave the characteristic impedance Z₀ of 50Ω was extended to 37 μm, by interleaving the plate member 60 (substrate spacer 62) between the back insulating layer 40 of the predetermined thickness and the metal base 210. This indicates that, based on the working example 1, the characteristic impedance Z₀ of the independent flexible wiring unit 100 can be maintained by only slightly reducing the line width L of the signal line 1030.

It is also understood that, while the distal end portion of the flexible wiring unit 100, 1100 is moved so that the back face of the flexible wiring unit gets in contact with and spaced from the metal base 210, 1210, interleaving the plate member 60 (substrate spacer 62) of the predetermined thickness as in the working example 1 allows significantly suppressing the fluctuation in characteristic impedance Z₀.

A first advantage from providing the shield layer 10 on the upper face of the front insulating layer 20 and interleaving the plate member 60 (substrate spacer 62) between the back insulating layer 40 and the metal base 210, as in the working example 1, is the shielding effect of electromagnetic wave by the shield layer 10. Besides, a desired characteristic impedance Z₀ can be attained with a sufficiently wide signal line 30, and further the fluctuation in characteristic impedance Z₀ arising from the movement of the distal end portion of the flexible wiring unit 100 can be suppressed.

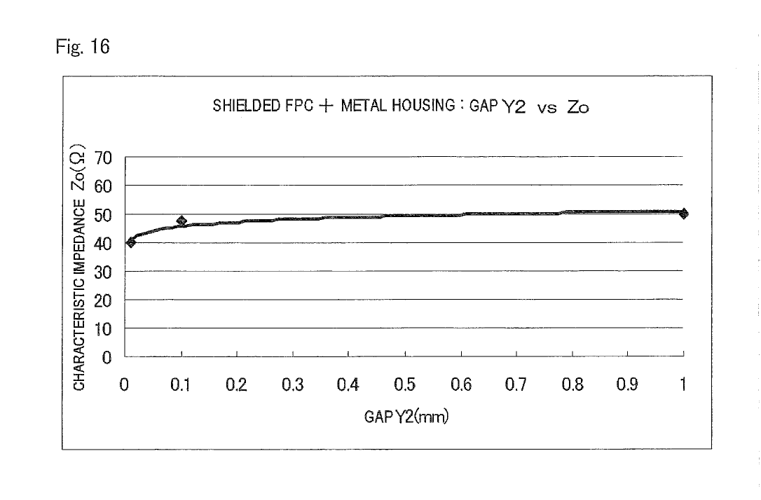

FIG. 16 is an enlarged drawing of FIG. 13(b), showing the characteristic impedance Z₀ of the flexible wiring unit 1100 corresponding to different gaps Y2 from 0 to 1 mm, and an approximation curve thereof.

From FIG. 13(b) and FIG. 16, it is understood that Z₀ sharply increases from 40Ω to 45Ω by widening the gap Y2 to approx. 0.07 mm=70 μm from 0 mm, but moderately increases thereafter. Then Z₀ reaches 50Ω with the gap Y2 of approx. 0.4 mm=400 μm, after which the characteristic impedance Z₀ barely fluctuates until the gap Y2 becomes 100 mm.

Accordingly, interleaving a non-conductive material having a dielectric constant close to air as the substrate spacer 62 between the back insulating layer 40 and the metal base 210, such that the gap Y2 becomes approx. 70 μm, allows sufficiently suppressing the fluctuation in characteristic impedance Z₀ of the flexible wiring unit 100.

In this case, the distance Y between the back face of the substrate spacer 62 and the signal line 30 is 105 μm, including the thickness of the back insulating layer 40 (25 μm) and the adhesive layer 32 (10 μm). On the other hand, the distance X between the lower face of the shield layer 10, 1010 and the signal line 30, 1030 in the working example 1 and the comparative example 2 is 35 μm as stated above. Thus, it is led that making Y three times or more as long as X according to this working example allows particularly effectively suppressing the fluctuation in characteristic impedance Z₀ arising from the movement of the distal end portion of the flexible wiring unit 100.

### Working Example 2

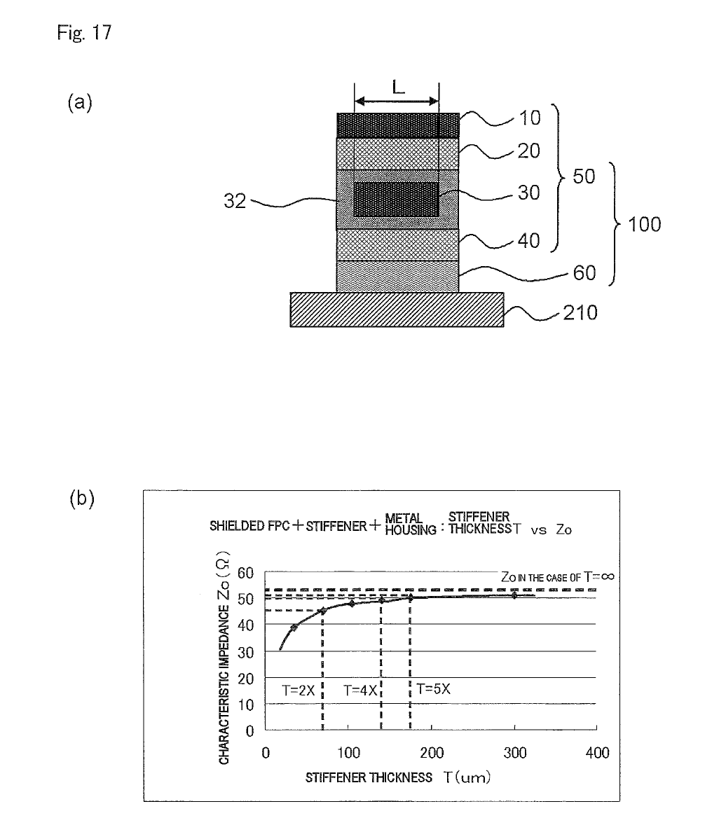

FIG. 17(a) is a schematic transverse cross-sectional view of the flexible wiring unit 100 according to a working example 2 in contact with the metal base 210.

The flexible wiring unit 100 according to this working example is different from that of the working example 1 only in that the thickness T of the plate member 60 (reinforcing plate) is changed in a plurality of sizes. In this working example also, the distance X between the lower face of the shield layer 10 and the signal line 30 is set as 35 μm.

Here, the distance Y between the back face of the plate member 60 and the signal line 30 corresponds to the total of the thickness T of the plate member 60, the back insulating layer 40 (25 μm), and the adhesive layer 32 (10 μm). In this working example, the total thickness of the back insulating layer 40 and the adhesive layer 32 is equal to the distance X. Therefore, a relationship of Y=T+X can be established.

FIG. 17(b) is a graph showing a simulation result of the characteristic impedance Z₀ corresponding to thicknesses T of the substrate spacer 62 that are an integer times of the distance X, and an approximation curve thereof. It should be noted, however, that the characteristic impedance Z₀ was calculated on the premise that the flexible wiring unit 100 is in contact with the surface of the metal base 210.

Also, the line width L of the signal line 30 according to this working example was set as 37 μm. This width was adopted from the line width L that gave the characteristic impedance Z₀ of 50Ω in the working example 1, in which the distance Y was set as approx. five times of the distance X. More specifically, making T equal to Y−X and nearly equal to 4X in FIG. 17(b) gives the characteristic impedance Z₀ of 50Ω. Also, the characteristic impedance Z₀ in the case where the gap Y3 is set as infinite in the working example 1 shown in FIG. 15(b), and the characteristic impedance Z₀ in the case where the thickness T is set as infinite in this working example both become close to approx. 52Ω.

Further, as shown in FIG. 17(b), the characteristic impedance Z₀ corresponding to the thickness T of an integer times of the distance X was 39Ω at T=X, 45Ω at T=2X, 48Ω at T=3X, and 49Ω at T=4X. Thus, in comparison with the characteristic impedance Z₀ (52Ω) corresponding to the infinite thickness T, the fluctuation in characteristic impedance is within a deviation of approx. 25% at T=X, approx. 13% at T=2X, approx. 8% at T=3X, and approx. 5% at T=4X.

Therefore, it is understood that making T equal to or greater than X, i.e. making Y equal to or greater than 2X as in this working example enables suppressing the fluctuation in characteristic impedance Z₀ of the flexible wiring unit 100 to a practically acceptable level, both in the case where the flexible wiring unit 100 is mounted on the metal base 210 and where these are sufficiently spaced from each other.

It is further understood that making T equal to or greater than 2X, i.e. making Y equal to or greater than 3X can make such suppression effect more prominent, and that further making T equal to or greater than 4X, i.e. making Y equal to or greater than 5X enables even suppressing the fluctuation in characteristic impedance Z₀ to a level within an error range.

1. A flexible wiring unit comprising:
a flexible substrate having flexibility in a longitudinal direction, including a signal line used for transmitting and receiving a signal to and from an external circuit, a front insulating layer and a back insulating layer with said signal line interleaved therebetween, and a conductive shield layer provided on an upper face of said front insulating layer so as to cover at least a part of said signal line;
a non-conductive substrate spacer provided so as to oppose a lower face of said back insulating layer;
a support member that sustains a longitudinal end portion of said flexible substrate;
the other longitudinal end portion of said flexible substrate being movably disposed;
wherein a distance Y between a back face of said substrate spacer and said signal line in a state where said flexible substrate is in contact with a surface of said substrate spacer is longer than a distance X between a lower face of said shield layer and said signal line.

2. The flexible wiring unit according to claim 1, wherein said shield layer is a ground layer for said signal line.

3. The flexible wiring unit according to claim 1, wherein said flexible substrate does not include a conductive layer between said signal line and said support member.

4. The flexible wiring unit according to claim 1, wherein said distance Y is three times or more as long as said distance X.

5. The flexible wiring unit according to claim 1, wherein a movement of said other end portion causes said flexible substrate and a surface of said substrate spacer to enter into mutual contact or to be spaced from each other.

6. The flexible wiring unit according to claim 1, wherein said support member and said substrate spacer are integrally formed.

7. The flexible wiring unit according to claim 1,
wherein a surface of said substrate spacer is joined to a lower face of said flexible substrate; and
said flexible substrate and said substrate spacer are interlockedly movable when said other end portion moves.

8. The flexible wiring unit according to claim 1, wherein said flexible substrate includes only one layer of said signal line.

9. The flexible wiring unit according to claim 1,
wherein said support member is non-conductive; and
a distance Z between a lower face of said support member and said signal line is three times or more as long as said distance X between said lower face of said shield layer and said signal line.

10. An electronic apparatus comprising:
a metal base;
a flexible substrate having flexibility in a longitudinal direction, including a signal line used for transmitting and receiving a signal to and from an external circuit, a front insulating layer and a back insulating layer with said signal line interleaved therebetween, and a conductive shield layer provided on an upper face of said front insulating layer so as to cover at least a part of said signal line;
a non-conductive substrate spacer provided so as to oppose a lower face of said back insulating layer, and a support member that sustains a longitudinal end portion of said flexible substrate, both located on said metal base;
wherein the other longitudinal end portion of said flexible substrate is movably disposed; and
a distance between said metal base and said signal line in a state where said flexible substrate is in contact with a surface of said substrate spacer is longer than a distance between a lower face of said shield layer and said signal line.
